(19) United States
(12) Patent Application Publication
(10) Pub. No.: US 2015/0340611 A1
(43) Pub. Date: Nov. 26, 2015

(54) METHOD FOR A DRY EXHUMATION WITHOUT OXIDATION OF A CELL AND SOURCE LINE

(71) Applicant: Sony Corporation, Tokyo (JP)

(72) Inventors: Kamran Akhtar, Boise, ID (US); Ashim Dutta, Boise, ID (US); Alex J. Schrinsky, Boise, ID (US); Shane J. Trapp, Boise, ID (US)

(73) Assignee: Sony Corporation, Tokyo (JP)

(21) Appl. No.: 14/283,893

(22) Filed: May 21, 2014

(51) Int. Cl. H01L 45/00

(52) U.S. Cl. CPC H01L 45/1666; H01L 45/085; H01L 45/14

(57) ABSTRACT

Various embodiments of the present invention are directed to a method for fabricating a memory cell comprising performing a passivation step on a cell structure and cell source lines prior to exhuming a masking layer to prevent oxidation of the cell structure and source lines.

### FIELD

Certain embodiments of the disclosure relate to a method for a dry exhumation without oxidation of the cell and source line.

### BACKGROUND

Multi-metallic films are being actively pursued as alternative memory technologies. Copper-containing CBRAM (Conductive Bridge Random Access Memory) cells are being developed using both subtractive and damascene process flows. The CBRAM damascene flow utilizes patterning of carbon, deposition of the CBRAM cell and copper source line, followed by a chemical-mechanical planarization (CMP) process and carbon exhumation. During conventional carbon exhumation processes, the copper surface in the cell and source line is exposed to oxygen plasma, and is therefore heavily oxidized, corrupting the structure of the copper lines. In some instances, oxidation is prevented by the use of a capping material or alternative metal source lines. However, this increases the resistivity of the source line and requires a more complicated and expensive structural and process integration scheme. Similarly high aspect ratio contacts landing on copper film require a blanket Barrier Low-k (BLOK) dielectric punch after a mask strip to protect the copper from oxidation during a conventional O₂ strip. This BLOK punch increases the top critical dimension (CD) significantly and is a critical impediment for scaling in cases where the contact CD is very small.

Therefore, there is a need in the art for a method to perform a dry exhume without oxidizing the copper source lines or copper cell, and without increasing the resistivity of the source lines in accordance with exemplary embodiments of the present invention.

### SUMMARY

A method is provided for a dry exhumation without oxidation of copper substantially as shown in and/or described in connection with at least one of the figures, as set forth more completely in the claims.

These and other features and advantages of the present disclosure may be appreciated from a review of the following detailed description of the present disclosure, along with the accompanying figures in which like reference numerals refer to like parts throughout.

### BRIEF DESCRIPTION OF THE DRAWINGS

FIGS. 1-6 depict a process for exhuming carbon without oxidizing the cell and the source line in a damascene flow.

FIG. 1 illustrates a first step in exhuming process in accordance with exemplary embodiments of the present invention;

FIG. 2 illustrates a second step in the exhuming process in accordance with exemplary embodiments of the present invention;

FIG. 3 illustrates a third step in the exhuming process in accordance with exemplary embodiments of the present invention;

FIG. 4 illustrates a fourth step in the exhuming process in accordance with exemplary embodiments of the present invention;

FIG. 5 illustrates a fifth step in the exhuming process in accordance with exemplary embodiments of the present invention; and

FIG. 6 illustrates a sixth step in the exhuming process in accordance with exemplary embodiments of the present invention;

FIGS. 7-11 depict a process for etching a via without contact critical dimension (CD) blowout in high aspect ratio contact etching in accordance with the exemplary embodiments of the present invention;

FIG. 7 illustrates a first step in exhuming process in accordance with exemplary embodiments of the present invention;

FIG. 8 illustrates a second step in exhuming process in accordance with exemplary embodiments of the present invention;

FIG. 9 illustrates a third step in exhuming process in accordance with exemplary embodiments of the present invention;

FIG. 10 illustrates a fourth step in exhuming process in accordance with exemplary embodiments of the present invention; and

FIG. 11 illustrates a fifth step in the etching process in accordance with exemplary embodiments of the present invention.

### DETAILED DESCRIPTION

Exemplary embodiments of the present invention are related to a method for dry exhumation without oxidation of a cell and source line. According to one embodiment, a typical damascene flow is enhanced with a fluorine-based plasma step applied in the dry exhume process. The fluorine reacts with the cell and source line (e.g., copper cell and copper source line) material to form a thin copper fluoride (CuFₓ) film. The copper-fluoride film protects the copper cell and copper source line material from oxidation during the oxygen-plasma based carbon exhume process.

In a typical damascene processing technique, the dielectric layer which is typically an oxide, commonly referred to as an intermetal dielectric (IMD) is deposited over the semiconductor surface. The oxide layer is polished so as to obtain a planar upper surface. A series of well-known process steps are then performed in order to form interconnects between various metal layers. The damascene process allows for the formation of small; closely spaced interconnects and contacts

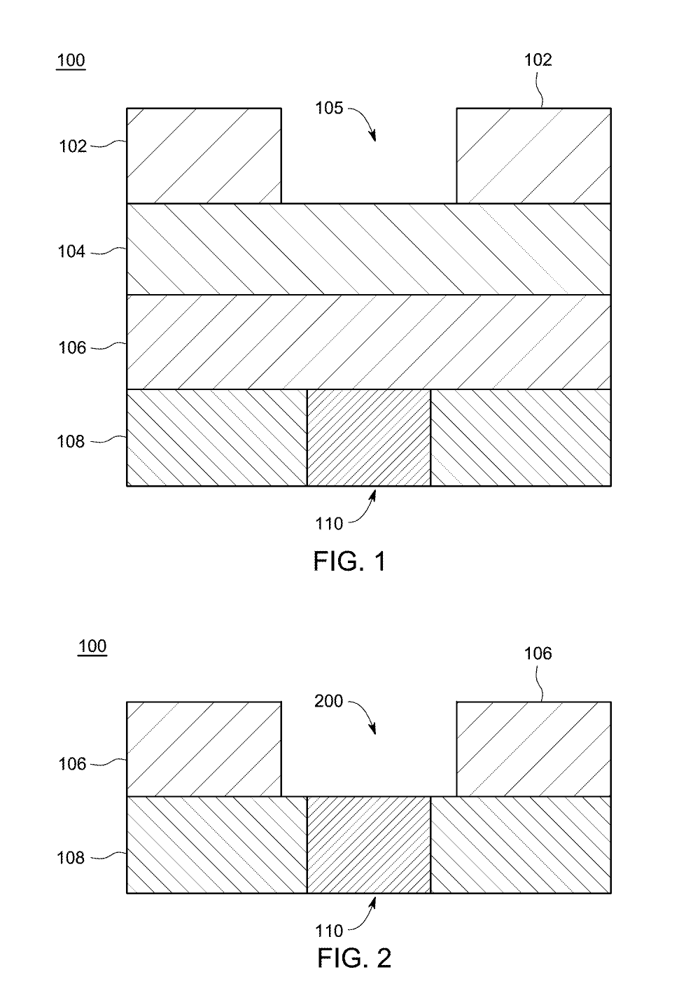

FIGS. 1-6 depict a process for exhuming carbon without oxidizing cell and source lines in a damascene flow.

FIG. 1 illustrates a first step in the exhuming process in accordance with exemplary embodiments of the present invention. A device 100 is shown which comprises a substrate 108 with metal contact 110 built into the device 100 using standard processes. A Carbon or underlayer (UL) dielectric layer 106 deposited atop the substrate 108. A masking layer 104 is deposited on the dielectric layer 106, and a photoresist layer 102 is deposited on the masking layer 104 and the photoresist layer 102 is patterned to form opening 105. Those of ordinary skill in the art will recognize that layer 106 may be something other than carbon, which can be exhumed and is not reactive to fluorine.

FIG. 2 illustrates a second step in the exhuming process in accordance with exemplary embodiments of the present invention. The masking layer 104 is etched using the patterned photoresist layer 102 to form a trench 200 in the dielectric layer 106. The trench 200 exposes the metal contact 110 and the substrate 108.

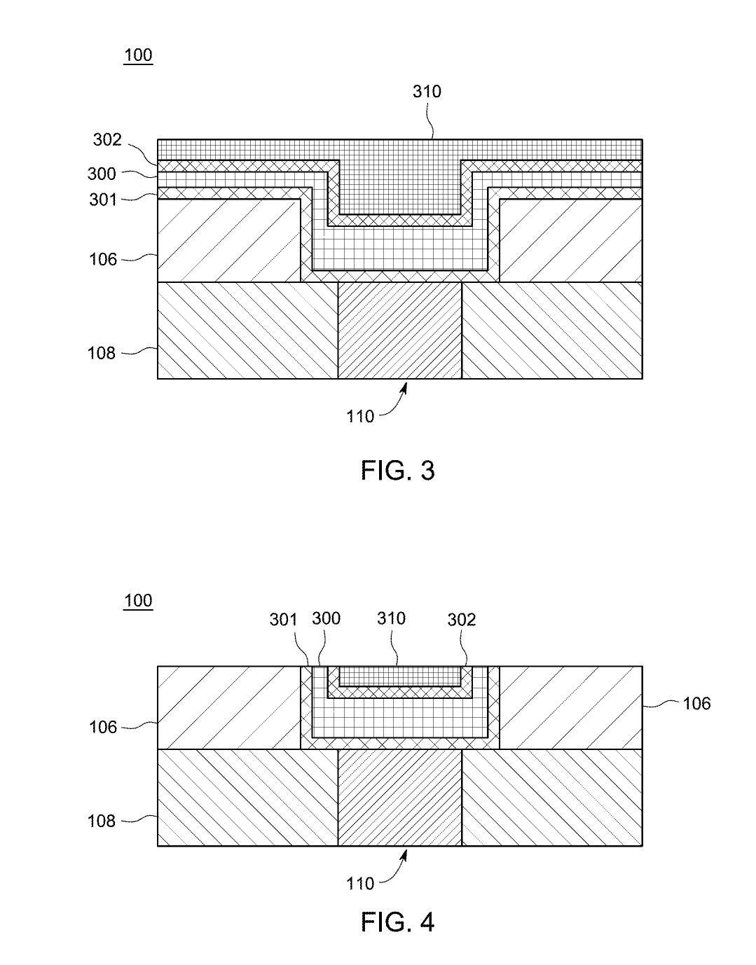

FIG. 3 illustrates a third step in the exhuming process in accordance with exemplary embodiments of the present invention. A barrier liner layer 301 is deposited in the trench 200. The barrier layer 301 may comprise, but is not limited to, CVD/ALD (Chemical Vapor Deposition/Atomic Layer Deposition) oxide and nitride in some embodiments. Subsequently, in some embodiments, copper (Cu) cell materials is deposited into the trench 200 to form the cell 300 and another conducting barrier metal (e.g., electromigration barrier metal) layer 302 is deposited on the cell 300 followed by another deposition of copper to form the source line 310. The barrier layer 301 and the barrier layer 302, the cell 300 and source line 310 have overburden above the plane of the dielectric layer 106.

FIG. 4 illustrates a fourth step in the exhuming process in accordance with exemplary embodiments of the present invention. The overburden is planarized using a chemical-mechanical planarization (CMP) process, leaving the copper surface of the cell 300 and the source line 310 exposed.

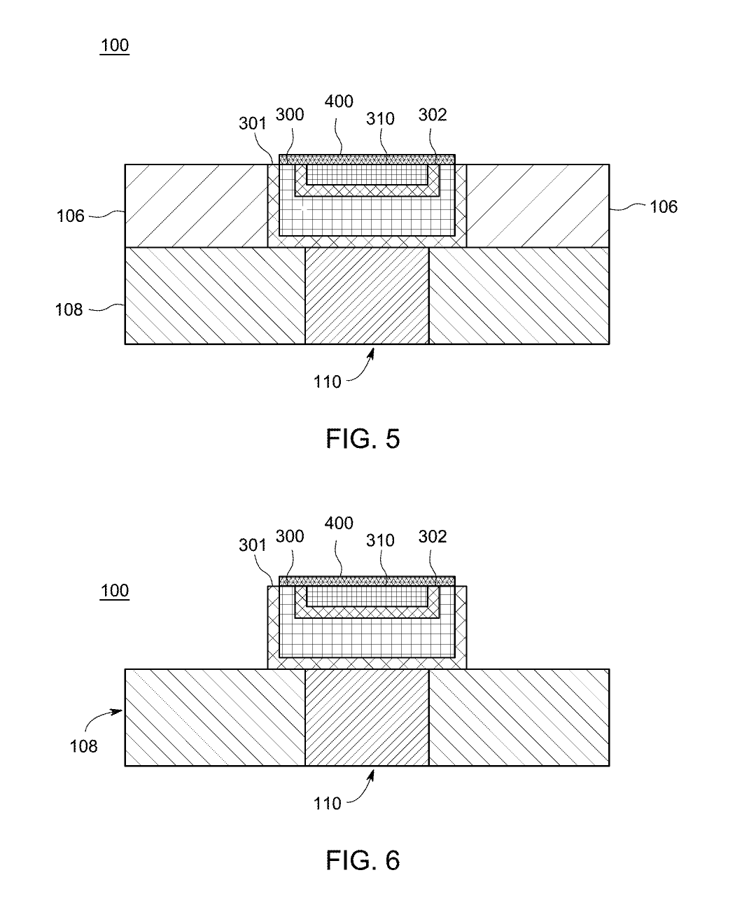

FIG. 5 illustrates a fifth step in the exhuming process in accordance with exemplary embodiments of the present invention. After CMP the exposed cell 300 and source line 310 are reacted with a fluorine based etchant in a passivation step. The in-situ fluorine reaction can be performed in a plasma-based process chamber of reactive sputtering type prior to exhume or strip processing. According to some embodiments, the fluorine based etchant may be CF4, SF6, NF3, CHF3, CH2F2 or any fluorine based compound which passivates copper. In this embodiment, the passivation gas is diluted with Ar (He) gas in a flow ratio of 1:2 with a total flow of 150 sccm at 40 mTorr. The plasma was created in a 13.56 MHz inductively coupled dry etch chamber at RF power of 500 W. According to this embodiment, the copper cell 300 and source line 310 are exposed to the fluorine based plasma for 25 seconds, though those of ordinary skill in the art recognize that different etchants and timings may be used as appropriate. The exposure of the copper to the fluorine results in the formation of a protective film 400 for the cell 300 and source line 310, the protective film 400 being composed of CuFₓ, for example. The protective film 400 acts as a barrier that protects the cell 300 and source line 310 against oxidation. The dielectric layer 106 is also exposed to the Fluorine but Fluorine is not reactive with the material of the dielectric layer 106, e.g., carbon or UL.

FIG. 6 illustrates a sixth step in the exhuming process in accordance with exemplary embodiments of the present invention. A dry exhume is performed, where an oxygen based plasma is used to exhume the dielectric layer 106 where protective film 400 protecting the cell 300 and source line 310 from oxidation. Normally, the oxygen plasma based exhume would cause the cell 300 and source line 310 to oxidize. However, the protective film 400 is impermeable by oxygen, thereby protecting the cell 300 and source line 310 from oxidation. The barrier layer 301 protects the side of the cell 300 from the oxygen plasma during exhumation.

After exhumation, the protective film 400 on the cell material 400 landing surface is sputtered clean using an in-situ H2, H2-Ar plasma, according to one embodiment. This step is optionally performed after the exhumation process when there is a concern regarding the fluorine interacting with substances applied to the device 100.

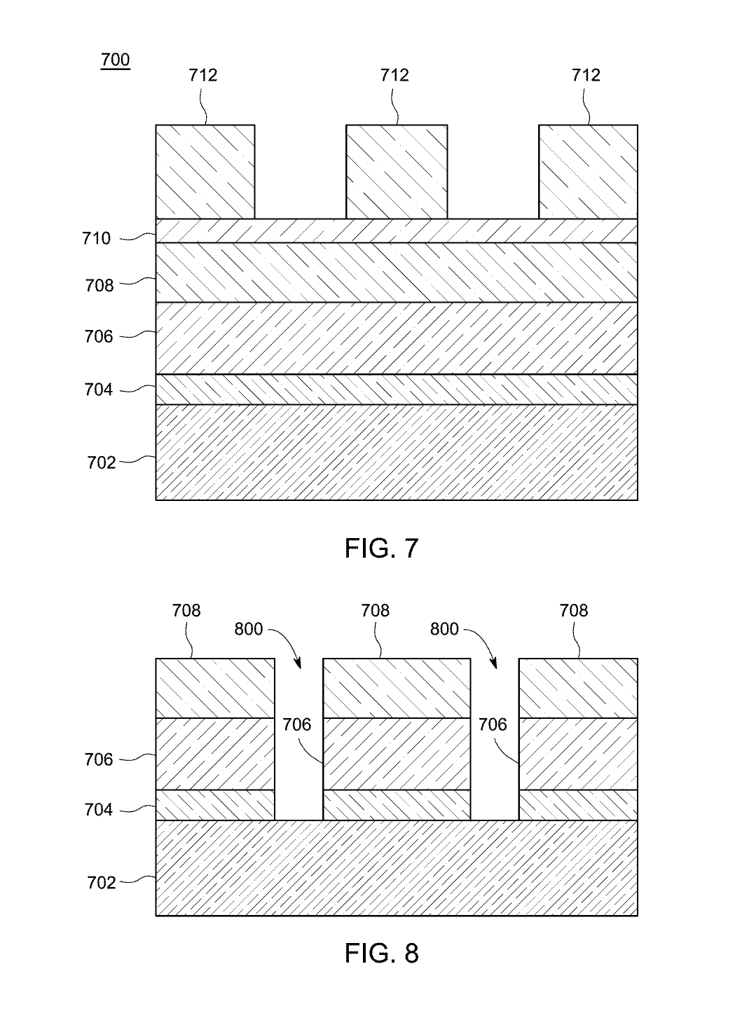

FIGS. 7-11 depict a process for etching a via without contact critical dimension (CD) blowout in high aspect ratio contact etching in accordance with the exemplary embodiments of the present invention.

FIG. 7 illustrates a first step in the etching process in accordance with exemplary embodiments of the present invention. The initial damascene process yields a device 700 comprising a copper film 702, a barrier dielectric film 704, a dielectric layer 706, masking layers 708 and 710 with a patterned photo resist layer 712. According to one embodiment, the film 704 is a Barrier low-k (BLOK) film (e.g., silicon carbide/silicon nitride) and the dielectric layer 706 is an oxide or nitride film. In this embodiment, the masking layer 708 is a carbon mask such as a carbon polymer or an under-layer (UL) mask and the masking layer 710 can be hard mask (HM) or Dielectric Anti-Reflection Coating (DARC) consisting of standard silicon oxynitride.

FIG. 8 illustrates a second step in the etching process in accordance with exemplary embodiments of the present invention. Vias 800 are etched into the masking layer 708, the dielectric layer 706 and barrier dielectric film 704 exposing the copper film 702.

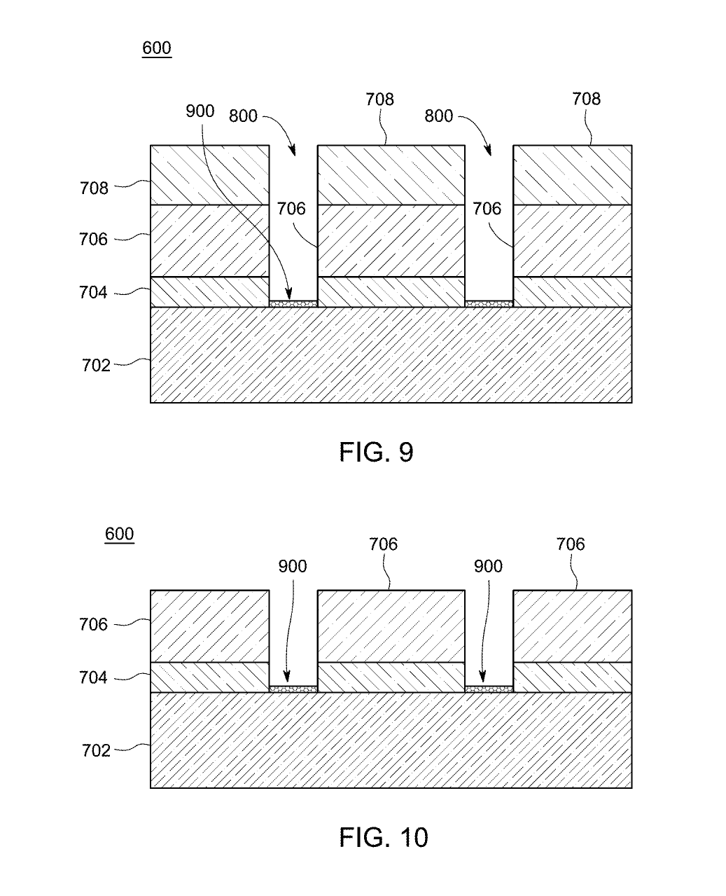

FIG. 9 illustrates a third step in the etching process. Copper passivation is performed by applying fluorine-based plasmas to portions of the exposed copper film 702. As described in FIGS. 1-6, the fluorine based compound reacts with the copper film 702 to create a protective film 900 formed of a copper-fluoride (CuFx) compound that acts as a passivation layer for the copper film 702. The fluorine based etchant may be CF4, SF6, NF3, CHF3, CH2F2, or any fluorine based compound which passivates copper. The fluorine passivation reaction is performed in a process chamber prior to exhume or strip processing. In some embodiments, the BLOK etch and the passivation step are combined, where the BLOK etching performed using a fluorine-based etch passivates the copper film 702.

FIG. 10 illustrates a fourth step in the etching process in accordance with exemplary embodiments of the present invention. The masking layer 708 is exhumed using an oxygen plasma based exhume process, removing the masking layer 708 and stopping at the dielectric layer 706. The protective film 900 prevents the copper film 702 from oxidation during the exhumation of masking layer 708. Since this process allows etching of barrier layer (BLOK) in the presence of selective mask, the integrity of contact top CD is maintained. In contrast, existing art mandates the exhumation of mask in the presence of barrier layer to prevent copper oxidation, followed by a blanket (without mask) BLOK punch to expose the copper layer resulting in contact top CD blow out.

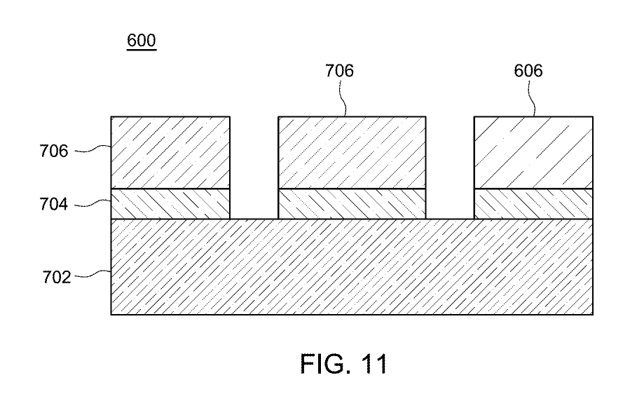

FIG. 11 illustrates a fifth step in the etching process in accordance with exemplary embodiments of the present invention. The protective film 900 is optionally removed using an in-situ H2, H2-Ar plasma based sputter clean after the masking layer 708 is exhumed to prevent future interaction between the fluorine and other compounds.

While the present disclosure has been described with reference to certain embodiments, it will be understood by those skilled in the art that various changes may be made and equivalents may be substituted without departing from the scope of the present disclosure. In addition, many modifications may be made to adapt a particular situation or material to the teachings of the present disclosure without departing from its scope. Therefore, it is intended that the present disclosure not be limited to the particular embodiment disclosed, but that the present disclosure will include all embodiments falling within the scope of the appended claims.

What is claimed is:

1. A method for fabricating a memory cell comprising:
performing a passivation step on a cell structure and a source line prior to exhuming a masking layer to prevent oxidation of the cell structure and the source line.

2. The method of claim 1, wherein the passivation step comprises:
forming a protective film on the cell structure and the source line using a compound which passivates a metal layer of the cell structure and the source line, wherein the protective film is formed from the reaction of the compound with the metal layer; and
exhuming the masking layer.

3. The method of claim 2, wherein the compound is a fluorine-based compound.

4. The method of claim 3, wherein the metal layer is copper.

5. The method of claim 4, wherein the fluorine based compound is one of CF4, SF6, NF3, CHF3, and CH2F2.

6. The method of claim 1, wherein the masking layer is one of carbon layer or an under layer (UL).

7. The method of claim 1, further comprising:
performing, as the passivation step in high aspect ratio contact etching, an etching of the masking layer, oxide/nitride layer and barrier dielectric layer, to expose the metal layer, wherein the etching is performed using a compound which passivates the metal layer by creating a protective film from the reaction of the compound with the metal layer; and
exhuming the masking layer.

8. The method of claim 7, wherein the compound is a fluorine based compound.

9. The method of claim 8, wherein the metal layer is copper.

10. The method of claim 9, wherein the fluorine based compound is one of CF4, SF6, NF3, CHF3 and CH2F2.

11. The method of claim 7, wherein contact critical dimension blowout is prevented by performing etching of multiple layers simultaneously in the presence of a masking layer.

12. The method of claim 7, wherein the oxide film is a Barrier Low-k (BLOK) film and the masking layer is one of a carbon film or underlayer film.

13. The method of claim 12, wherein exhuming the masking layer is performed using an oxygen based plasma.

14. The method of claim 13, wherein the BLOK film is a film deposited on the metal layer and is thinner than the metal layer.

15. The method of claim 2, further comprising removing the protective film from cell structure to prevent interaction of the compound with later applied processes.

16. The method of claim 15, wherein removing the protective film from the cell structure is performed by sputter cleaning.

17. The method of claim 16, wherein the sputter cleaning is performed using in-situ H2 or H2-Ar plasma.

18. The method of claim 7, further comprising removing the protective film from cell structure to prevent interaction of the compound with later applied processes.

19. The method of claim 18, wherein removing the protective film from the cell structure is performed by sputter cleaning.

20. The method of claim 19, wherein the sputter cleaning is performed using in-situ H2 or H2-Ar plasma.
